(19) United States
(12) Patent Application Publication
(10) Pub. No.: US 2012/0038252 A1
(43) Pub. Date: Feb. 16, 2012

(54) MOUNTING APPARATUS FOR POWER SUPPLY

(75) Inventors: YUN-LUNG CHEN, Tu-Cheng (TW); DA-LONG SUN, Shenzhen City (CN); SHENG-HE LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/036,046

(22) Filed: Feb. 28, 2011

(30) Foreign Application Priority Data
Aug. 10, 2010 (CN) 201010249715.2

(51) Int. Cl. H05K 5/02; H05K 7/14

(52) U.S. Cl. 312/223.2; 248/224.8

(57) ABSTRACT

A mounting apparatus includes a computer case and a supporting member. The computer case includes a bottom plate and a rear plate connected to the bottom plate. An opening is defined in the rear plate. A positioning assembly extends from an edge of the opening for positioning a power supply. The positioning assembly includes a first positioning panel substantially perpendicular to the bottom plate, and a second positioning panel substantially parallel to the bottom plate. The supporting member is attached to the bottom plate. A first retaining piece is disposed on the supporting member. The first retaining piece is substantially perpendicular to the bottom plate, for sustaining the power supply. The first positioning panel and the first retaining piece are located in a same plane, and the second positioning panel is attached to a top panel of the power supply.

### BACKGROUND

1. Technical Field

The present disclosure relates to mounting apparatuses, and particularly to a mounting apparatus for securing a power supply to an electronic device.

2. Description of Related Art

A conventional computer system usually includes a power supply unit in a computer case. The installation of the power supply unit in the computer case usually involves the use of screws, which is inconvenient. Furthermore, the volume of the power supply unit is usually so big that the power supply unit sometimes deforms a rear plate of the computer case.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric, cutaway view of a mounting apparatus in accordance with an embodiment.

FIG. 2 is an assembled, cutaway view of FIG. 1.

FIG. 3 is similar to FIG. 2, but shows a power supply in a different position.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

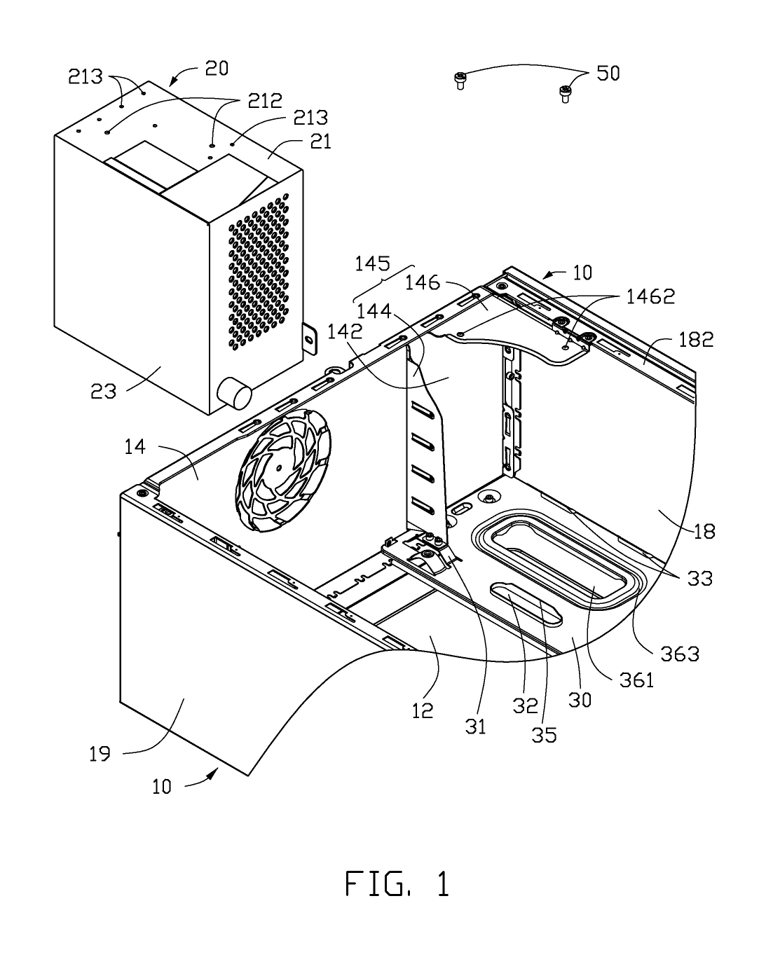

Referring to FIG. 1, a mounting apparatus, according to one embodiment, is configured for securing a power supply 20 and includes a computer case 10 and a supporting member 30.

The power supply 20 includes a top panel 21 and a side panel 23. Two mounting holes 212 are defined in the top panel 21, and a plurality of protuberances 213 are disposed on the top panel 21. In one embodiment, the top panel 21 is substantially perpendicular to the side panel 23.

The computer case 10 includes a bottom plate 12, a rear plate 14 connected to the bottom plate 12, a first side plate 18 connected to the rear plate 14 and the bottom plate 12, and a second plate 19 connected to the rear plate 14 and the bottom plate 12. In one embodiment, the first and second side plates 18, 19 are substantially parallel to each other and perpendicular to the bottom plate 12. A flange 182 is connected to the first side plate 18 and extends into the computer case 10.

An opening 142 is defined in the rear plate 14, and a positioning assembly 145 extends from the opening 142. The opening 142 is adjacent to the first plate 18. The positioning assembly 145 includes a first positioning panel 144 and a second positioning panel 146. The first positioning panel 144 is away from the first plate 18. The second positioning panel 146 is connected to the rear plate 14 and the flange 182 of the first side plate 18. In one embodiment, the second positioning panel 146 is mounted to the flange 182 by any suitable means, such as jointing or with screws. Two positioning holes 1462 are defined in the second positioning panel 146, corresponding to the two mounting holes 212. In one embodiment, the first positioning panel 144 is substantially perpendicular to the bottom plate 12; and the second positioning panel 146 is substantially parallel to the bottom plate 12.

The supporting member 30 is attached to the bottom plate 12 and abuts the first side plate 18. A bridge 31 is located on the supporting member 30, for securing the first positioning panel 144. A first through hole 32 and a second through hole 361 are defined in the supporting member 30, and the second through hole 361 is larger than the first through hole 32. A first retaining piece 35 extends from an edge of the first through hole 32. A concave configuration 363 surrounds the second through hole 361, for strengthening the configuration of the supporting member 30. Two second retaining pieces 33, adjacent to the first side plate 18, are located an edge of the support member 30. In one embodiment, the first retaining piece 35 and the first positioning panel 144 are located at a same plane; and the two second retaining pieces 33 are arranged in a line substantially perpendicular to the rear plate 14.

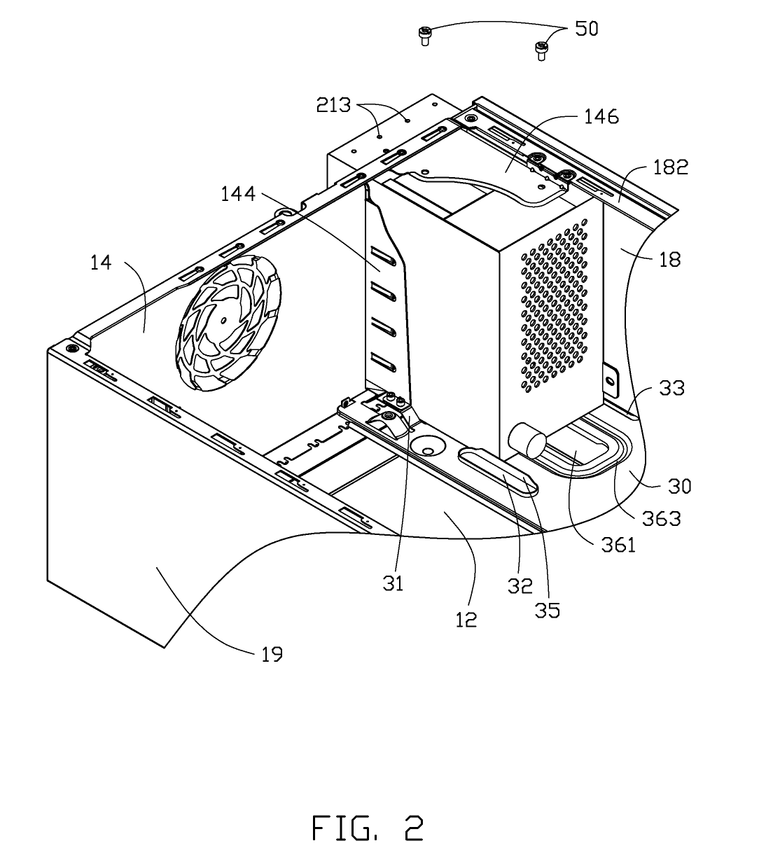

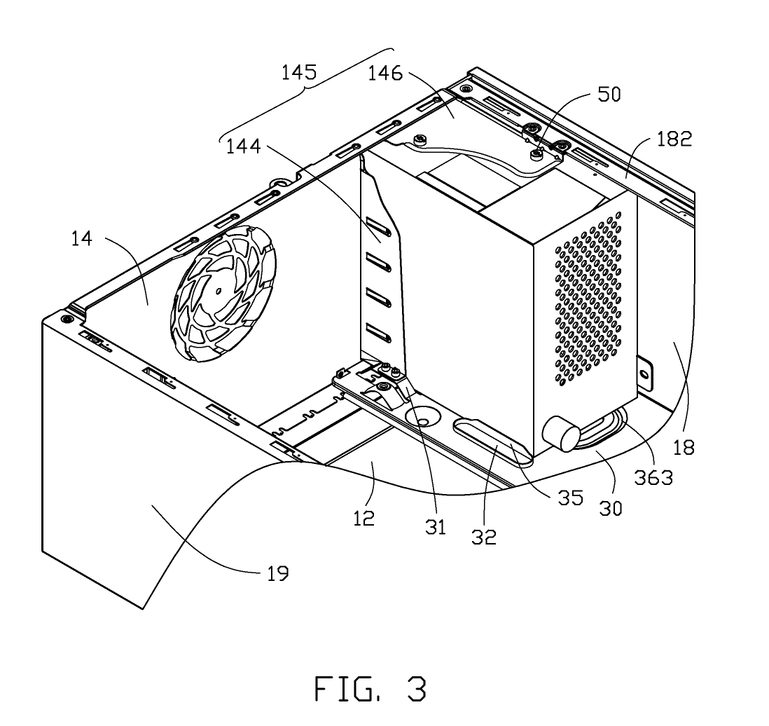

Referring to FIGS. 2 and 3, in assembly, the power supply 20 is inserted into the opening 142 and moved in a first direction perpendicular to the rear plate 14. The side panel 23 abuts the first positioning panel 144, a side panel (not shown) opposite to the side panel 23 abuts the first side plate 18, and the top panel 21 abuts the second positioning panel 146. The power supply 20 is further moved in the first direction, until the power supply 20 is located between the first retaining piece 35 and the second retaining piece 33. The two mounting holes 213 of the top panel 21 are aligned with the two positioning holes 1462 of the second positioning panel 146. Two fixing members 50 are respectively inserted into the two mounting holes 213 and the two positioning holes 1462, to mount the top panel 21 to the second positioning panel 146.

In disassembly, the two fixing members 50 are removed from the second positioning panel 146 and the top panel 21. The power supply 20 is moved in a second direction opposite to the first direction, and pulled out from the computer case 10.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A mounting apparatus comprising:
a computer case comprising a bottom plate and a rear plate connected to the bottom plate, an opening defined in the rear plate, a positioning assembly extending from an edge of the opening for positioning a power supply, the positioning assembly comprising a first positioning panel substantially perpendicular to the bottom plate, and a second positioning panel substantially parallel to the bottom plate; and
a supporting member attached to the bottom plate, a first retaining piece disposed on the supporting member, the first retaining piece substantially perpendicular to the bottom plate, for sustaining the power supply;
wherein the first positioning panel and the first retaining piece are located in a same plane, and the second positioning panel is attached to a top panel of the power supply.

2. The mounting apparatus of claim 1, wherein the computer case comprises a first side plate connected to the rear plate, and the first positioning panel is substantially parallel to the first side plate.

3. The mounting apparatus of claim 1, wherein a bridge is located on the supporting member, and the bridge is secured to the first positioning panel.

4. The mounting apparatus of claim 1, wherein a flange is connected to the first side plate, and the flange is mounted to the second positioning panel.

5. The mounting apparatus of claim 1, wherein a second retaining piece is located on the supporting member, and the first retaining piece and the second retaining piece are configured to position the power supply therebetween.

6. The mounting apparatus of claim 5, wherein a first through hole is defined in the supporting member, the first retaining piece extends from an edge of the first through hole, and the second retaining piece abuts the first side plate.

7. The mounting apparatus of claim 6, wherein a second through hole is defined in the supporting member, and a concave configuration surrounds the second through hole.

8. A mounting apparatus comprising:
a computer case comprising a bottom plate, a first side plate connected to the bottom plate, and a rear plate connected to the bottom plate and the first side plate, a positioning assembly located on the rear plate, comprising a first positioning panel abutting a side panel of a power supply, and a second positioning panel abutting a top panel substantially perpendicular to the side panel; and
a supporting member attached to the bottom plate and secured to the first positioning panel, a first retaining piece and a second retaining piece disposed on the supporting member, for abutting two opposite side panels of the power supply, the first retaining piece and the first positioning panel are located in a same plane, and the second retaining piece abuts the first side plate.

9. The mounting apparatus of claim 8, wherein an opening is defined in the rear plate, and the first positioning panel extends from the first side plate.

10. The mounting apparatus of claim 9, wherein the first positioning panel is substantially perpendicular to the bottom plate.

11. The mounting apparatus of claim 8, wherein a bridge is located on the supporting member, and the bridge is secured to the first positioning panel.

12. The mounting apparatus of claim 8, wherein the second positioning panel is substantially parallel to the bottom plate.

13. The mounting apparatus of claim 8, wherein a flange is connected to the first side plate, and the flange is mounted to the second positioning panel.

14. The mounting apparatus of claim 8, wherein a first through hole is defined in the supporting member, and the first retaining piece extend from an edge the first through hole.

15. The mounting apparatus of claim 8, wherein a second through hole is defined in the supporting member, and a concave configuration surrounds the second through hole.
